(19) United States
(12) Patent Application Publication
(10) Pub. No.: US 2023/0106007 A1
(43) Pub. Date: Apr. 6, 2023

(54) DRIVE UNIT OF AN ELECTRICAL POWER-ASSISTED STEERING SYSTEM FOR A MOTOR VEHICLE

(71) Applicants: thyssenkrupp Presta AG, Eschen (LI); thyssenkrupp AG, Essen (DE)

(72) Inventors: Manuel DUERIG, Buchs SG (CH); Raphael GERNER, Eschen (LI); Brice HOUMPE TSAGUE, Widnau (CH); Thomas PFISTER, Goetzis (AT); Julian SANDHOLZER, Altach (AT)

(73) Assignees: thyssenkrupp Presta AG, Eschen (LI); thyssenkrupp AG, Essen (DE)

(21) Appl. No.: 17/801,762

(22) PCT Filed: Feb. 18, 2021
(86) PCT No.: PCT/EP2021/053932

§ 371 Date: Aug. 23, 2022

(30) Foreign Application Priority Data
Feb. 24, 2020 (DE) 10 2020 202 340.9

(51) Int. Cl. B62D 5/04

(52) U.S. Cl. CPC B62D 5/0406

(57) ABSTRACT

A drive unit for an electrical power-assisted steering system of a motor vehicle may include an electric motor with a stator housing to which a control housing, in which a control circuit board is arranged, is attached, and with a connecting unit, attached to the stator housing, which has electrical connecting elements and at least one positioning element. The connecting elements are electrically connected to the electric motor and to the control circuit board. The positioning element interacts with the control circuit board for the purpose of relative positioning. To enable simpler and more secure mounting, the positioning element interacts with the control housing for the purpose of relative positioning.

### PRIOR ART

The invention relates to a drive unit for an electrical power-assisted steering system of a motor vehicle, comprising an electric motor with a stator housing to which a control housing, in which a control circuit board is arranged, is attached, and with a connecting unit, attached to the stator housing, which has electrical connecting elements and at least one positioning element, wherein the connecting elements are electrically connected to the electric motor and to the control circuit board, and the positioning element interacts with the control circuit board for the purpose of relative positioning.

In the prior art, motor vehicle steering systems with power assistance are known, in which, in addition to the steering torque which is exerted on the steering wheel manually by the driver, power assistance, and possibly also an additional steering angle, is introduced into the steering train by electromechanical power assistance in order to assist and reduce the effort required by the driver.

The power assistance is generated by means of an electrical power-assistance drive which has a drive unit with an electric motor, the rotor shaft of which is coupled to the steering train via a power-assistance gearbox.

A generic drive unit is known in the prior art, for example, from DE 10 2018 216 744 A1. It comprises a motor with a stator housing, in which the stator or phase windings are attached, and in which the rotor, with the rotor shaft situated axially, is mounted rotatably. The motor is electrically actuated by an electrical control circuit which has electrical components arranged and interconnected on a control circuit board, also referred to as a printed circuit board or PCB. This control circuit board is arranged in a control housing, also referred to as a control circuit board housing, which is connected to the stator housing to form a compact module, which is also referred to as a power pack. The phase windings of the motor and the control circuit board are connected electrically and mechanically via a connecting unit. The latter is at one side fixed to the stator housing and electrically connected to the phase windings of the motor, and at the other side is connected to the control housing and electrically connected to the control circuit board.

In the case of the known drive unit, the connecting unit has positioning elements in the form of positioning pins which engage in form-fitting fashion in corresponding socket openings in the control circuit board. As a result, the positioning elements interact with the control circuit board in such a way that positioning and alignment of the control circuit board relative to the connecting unit and hence to the stator housing is effected. In its mounted state, the control circuit board is accommodated in the control housing in a protected fashion. It is, however, disadvantageous here that the control housing is not aligned, or only insufficiently, relative to the control circuit board. The control housing is namely for its part fastened to the stator housing or the connecting unit. Because the tolerances of the connections between the stator housing, the connecting unit, and the control circuit board with respect to the alignment of the control circuit board are added to one another, it can be more difficult to mount the control circuit board and there is an increased risk of damage during mounting.

In light of the problem explained above, an object of the present invention is to enable simpler and more secure mounting of a drive unit.

### DESCRIPTION OF THE INVENTION

This object is achieved according to the invention by the drive unit having the features of claim 1, and the method for producing a drive unit as claimed in claim 9. Advantageous developments are the subject of the subclaims.

In the case of a drive unit for an electrical power-assisted steering system of a motor vehicle, comprising an electric motor with a stator housing to which a control housing, in which a control circuit board is arranged, is attached, and with a connecting unit, attached to the stator housing, which has electrical connecting elements and at least one positioning element, wherein the connecting elements are electrically connected to the electric motor and to the control circuit board, and the positioning element interacts with the control circuit board for the purpose of relative positioning, it is provided according to the invention that the positioning element interacts with the control housing for the purpose of relative positioning.

The electric motor is particularly preferably arranged in the stator housing which comprises a stator with stator or phase windings and in which a rotor, with the rotor shaft situated axially, is mounted rotatably.

The connecting unit is positioned and fixed on the stator housing and provides at least one positioning element according to the invention, preferably a plurality of positioning elements. According to the invention, the positioning element is configured and designed in order to enable both the control circuit board and the control housing to be aligned precisely relative to the connecting unit. In other words, the control circuit board and the control housing are each aligned directly on the positioning element and are hence positioned and aligned relative to the connecting unit parallel to each other on the same positioning element, and not via a serial arrangement of connections as in the prior art. The unavoidable and potentially damaging adding-up of the tolerances of the serially arranged connections in the prior art is thus avoided and an improved and more precise positioning of the control circuit board and the control housing is ensured. By virtue of the improved dimensional accuracy of the arrangement, mounting, in particular in the case of automated manufacturing, is simplified. The relative orientation between the control housing and the positioning element is largely independent of tolerances such that a correspondingly precise alignment of the control circuit board relative to the control housing is ensured by the alignment according to the invention of the control circuit board on this positioning element. By virtue of this reproducible, low-tolerance alignment, mounting is simplified and there is a reduced risk of damage due to relative faulty orientations when the control circuit board is inserted into the control housing and when the connections between the connecting unit and the control circuit board are joined together.

The advantageous effects are achieved in particular by the positioning element or elements according to the invention first providing a common reference position for aligning and orienting the control housing and the control circuit board, as a result of which tolerance-related problems and the risk of damage during mounting can be reduced and largely avoided.

The control housing can be fixed, for example flange-mounted, to the stator housing, for example by means of fastening bolts which are passed and screwed through corresponding fastening bores. By virtue of a sufficiently large predetermined play, fixing in the relative position defined by the positioning elements can be effected. The control housing can preferably be secured to the outside of the stator housing, for example frontally with respect to an axial direction which is defined by the rotor axis, for example by a flange connection. Alternatively or additionally, detachable and/or undetachable connecting means can be provided for the purpose of fixing the relative position, predetermined by the positioning element or elements according to the invention, of the control housing with respect to the connecting unit and to the stator housing.

The alignment and fixing of the control circuit board can be effected on the positioning element or elements according to the invention when the control housing is positioned and fixed relative to the positioning elements. The control circuit board can here be connected detachably or undetachably to at least one positioning element, or alternatively or additionally to the control housing.

The simultaneous positioning and fixing of the control circuit board on a positioning element has the advantage of efficient mounting. The positioning element or elements can simultaneously serve as fastening elements or connecting elements between the connecting unit and the control circuit board and/or the control housing. Fixing can be effected detachably or undetachably, for example by soldering, adhesive bonding, press-fitting, screwing, clamping, or the like. It is conceivable and possible here for the connection to be configured so that it is electrically conductive and for an electrical connection between the connecting unit and the control circuit board to be produced by means of an electrically conductive positioning element. The manufacturing and mounting cost can be reduced as a result. Thus, some positioning elements are designed as phase plugs of the electric motor, whilst the other positioning elements serve for positioning.

The control housing can protrude outward beyond the cross-section of the stator housing, for example laterally transversely to the axial direction of the rotor axis. It is consequently possible to use a control circuit board which is larger than the installation space available in the internal cross-section of the stator housing. This furthermore enables improved cooling of the electronic components attached to the control circuit board. These are further advantages compared with the prior art where the control circuit board is arranged, together with the control housing, inside the stator housing, as a result of which the installation space and the possibility of heat transfer can be limited.

It can be provided that at least one positioning element engages in form-fitting fashion in a corresponding positioning socket in the control housing. For this purpose, the positioning socket can have, for example, a recess or a preferably axial through opening into which the positioning element can be inserted in a mounting direction in order to form the form-fit. The mounting direction can preferably correspond to the axial direction and the form-fit can be effective in this direction and/or transversely thereto. The positioning element or elements can likewise engage in corresponding positioning sockets in the control circuit board, for example in form-fitting fashion in recesses or through openings.

An effective embodiment which can be implemented at low cost is that at least one positioning element has a positioning pin which is aligned in an axial direction of the motor. The connecting unit can preferably be attached to the stator housing in such a way that one or more positioning pins project axially at the front. The positioning sockets, corresponding thereto, in the control housing and the control circuit board can be designed simply as openings or recesses in which the positioning pin can be housed simply by being pushed in axially. An axial through opening can preferably be provided, for example in the control housing, through which a positioning pin can be pushed in the axial direction. The control circuit board can be positioned and optionally fixed with a corresponding positioning socket, likewise a recess or an opening, on a section of the positioning pin which projects axially from the through opening of the control housing, a positioning section. Such an arrangement of positioning pins and corresponding positioning sockets can be formed at low cost and enables simple and secure mounting. During the mounting, first the control housing, and then the control circuit board, can be pushed onto the positioning pin or pins.

A positioning pin can have a circular or a non-round cross-section, for example a polygonal or otherwise shaped cross-section, which corresponds to an internal cross-section of a socket opening of a positioning socket. Simple insertion in the axial direction can be enabled as a result, which corresponds to an axial mounting direction. A form-fit can be produced transversely to the mounting direction by a corresponding adaptation of the shape and dimensions. A defined play can optionally also be provided, for example by forming an elongated hole or slot, as a result of which tolerances in one direction can be compensated which do not negatively affect the relative alignment according to the invention of the control housing and the control circuit board.

It is possible that at least one positioning element or one connecting element projects further from the stator housing relative to another positioning element or connecting element. In other words, the at least one positioning element which projects further is thus longer than the other positioning element or elements or than the other connecting element or elements. The longer positioning element is preferably at least 1 mm longer or at least 2 mm longer than the other positioning or connecting element. Because a positioning element which is preferably designed as a positioning pin projects further axially, in the axial direction, it can be inserted axially into a corresponding positioning socket, preferably a socket opening, wherein further relative orientation is possible of the other positioning element or elements which are situated further back axially with respect to the mounting direction and have not yet engaged in the corresponding positioning sockets. As soon as one or alternatively two positioning elements have been inserted in form-fitting fashion in the defined installation position, the other positioning elements are automatically aligned with respect to the corresponding positioning sockets and can be mounted by further axial movement. Mounting can be simplified as a result.

It can be provided that at least one positioning element has at least one first positioning section for engaging in the control housing and at least one second positioning section for engaging in the control circuit board. The first positioning section can, for example, have a larger cross-section than the second positioning section, for example a larger diameter in the case of a positioning pin. A positioning pin which is stepped in the axial direction can, for example, be formed. The control housing can be pushed in form-fitting fashion onto the first positioning section with a positioning socket formed as a through opening in an axial mounting direction over the second positioning section. In the finished mounting state, when the control housing sits and is fixed on the first positioning section, the second mounting section projects axially from the control housing. The control circuit board can now be pushed onto this projecting second positioning section until the second positioning section sits in form-fitting fashion in the corresponding positioning socket of the control circuit board. As a result, the control circuit board can be aligned relative to the positioning element and hence simultaneously relative to the control housing.

The positioning sockets of the control housing and the control circuit board can have different diameters compared with the other positioning sockets so that the at least one longer and axially further projecting positioning element can be positioned and pushed through more simply.

It is possible that at least one positioning element has a connecting element. As a result, a connecting element can be formed so that it is integrated with a positioning element. For example, a connecting or contact element can have a positioning pin with an integrated electrical conductor, for example made from a metal material. The contact element can be designed, for example, as a contact pin made from a wire.

It is possible that a connecting element has a coating of non-conductive material at least in some places. One or more connecting elements can, for example, each have a contact pin which additionally can also have a positioning section of a positioning element or serve as the latter. One or more such connecting elements or contact pins can, for example, be coated with a plastic overmolding made from a thermoplastic, electrically insulating plastic. In this way, the coating can have one or more insulated sections which can also be designed as positioning sections of a positioning element according to the invention.

The contact pins can be provided as preferably bent wire sections which have positioning sections which project axially from the plastic in the direction of the rotor axis. Connecting sections can in each case be provided at the end regions remote with respect to the positioning sections for conductive connection to the wire ends of the phase windings. The connecting sections can be angled in order to simplify the process for mounting and producing a conductive connection, for example by crimping or welding.

For embedding in the connecting bodies, the finished bent contact pins can be laid in the injection mold and then be overmolded with molten plastic. The positioning sections then project from the plastic as bare wire sections.

An advantageous development can provide that a plurality of positioning elements are designed so that they are connected to one another in a single piece, preferably as a plastic injection-molded part. As a result, a connecting unit, including the positioning elements, can be made available as an injection-molded part, preferably made from a thermoplastic, in a favorable manner from a manufacturing technology point of view and with low dimensional tolerances. An advantageous development can provide that one or more connecting elements, for example metal contact pins, are embedded in the plastic injection-molded part of the connecting unit. It can be particularly advantageous here to embed a connecting or contact element in a positioning element. Advantageous multifunctionality is enabled by this integration: for example, a stepped positioning pin can as described above be provided in the plastic injection-molding process at low cost and with a high degree of accuracy, and a plurality of such positioning pins can be integrated with a connecting unit as a single piece.

In order to mount the connecting unit on the stator housing, it can preferably be provided that corresponding fastening elements are provided which are fixed detachably or undetachably to one another. The fastening elements are preferably configured and designed such that they can be joined together in an axial mounting direction in order subsequently to be fixed in place. For example, the fastening elements can have studs, so-called bobbins, and corresponding socket openings which can be joined together in form-fitting fashion. An undetachable connection can be effected effectively, securely, and dimensionally accurately by means of welding, adhesive bonding, caulking, riveting, or the like.

An advantageous development can provide that the control housing is closed on its side remote from the stator housing with a control housing lid such that the electronic components of the control circuit board and other sensitive elements of the motor are protected from dirt and moisture.

The invention furthermore relates to a method for producing a drive unit for an electrical power-assisted steering system of a motor vehicle, in which a control housing, in which a control circuit board is arranged, is attached to a stator housing of an electric motor, wherein a connecting unit having electrical connecting elements and at least one positioning element is attached to the stator housing, comprising the steps:
positioning and fixing the connecting unit on the stator housing,
aligning the control housing on the positioning element of the connecting unit and fixing relative to the stator housing,
aligning the control circuit board on the positioning element and fixing it relative to the stator housing.

In the method according to the invention, all of the features and procedures mentioned above in connection with the design of the drive unit according to the invention can be employed.

A stator housing is first provided in which the rotor of the electric motor can be mounted rotatably so that it is ready for operation. A connecting unit can preferably, as described above, be fixed to the stator housing frontally in the axial mounting direction. For example, corresponding fastening elements of the connecting unit and the stator housing can preferably be joined to one another and fixed to one another in form-fitting fashion in an axial mounting direction. As a result, the connecting unit is fixed in position relative to the stator housing in such a way that the positioning element or elements according to the invention are positioned and aligned for subsequent mounting of the control housing. The positioning elements can preferably have at least one positioning pin which projects axially at the front, preferably a plurality of pin-shaped elongated positioning pins.

The control housing is then aligned on at least one positioning element of the connecting unit and fixed relative to the stator housing. During the alignment, one or more fastening sockets, preferably through openings, are arranged axially aligned in front of the corresponding positioning elements, preferably positioning pins. The control housing is pushed onto the connecting unit in the axial direction by an axial mounting movement until the positioning pins penetrate the corresponding positioning openings preferably in a form-fitting fashion and thus preferably sit on corresponding first positioning sections. The positioning elements preferably here project axially beyond the control housing with second positioning sections. Thanks to the invention, these second positioning sections are positioned precisely relative to the control housing solely by simply pushing them on.

The control circuit board is then aligned on the positioning element and fixed relative to the stator housing. For the purpose of alignment, a corresponding positioning socket, for example an axial positioning opening in the control circuit board, is arranged axially aligned in front of the positioning element which is preferably designed as a positioning pin. The control circuit board is then moved in an axial mounting direction toward the control housing until it is inserted therein and the said second positioning sections of the positioning pin or pins penetrate the corresponding positioning openings of the control circuit board in form-fitting fashion. As a result, the control circuit board is automatically aligned on the positioning element or elements and hence simultaneously relative to the control housing.

The fixing of the control circuit board can then be effected detachably or undetachably, for example by soldering, adhesive bonding, press-fitting, screwing, clamping, or the like. It is conceivable and possible here to configure the connection so that it is electrically conductive. The control circuit board can preferably be secured on the positioning element or elements. By virtue of the fixing of the control circuit board, the control housing arranged below the control circuit board with respect to the mounting direction can simultaneously also be fixed to the connecting unit.

The connecting unit is preferably electrically connected to the stator windings via electrical connecting elements and electrically connected to the control circuit board by means of connecting elements. The connecting elements can be integrated into the positioning elements and, for example, have a conductive pin which is preferably connected mechanically and electrically to the control circuit board via an electrically conductive connection such as soldering or the like.

An advantage of the method according to the invention is that, when mounting the control housing, the positioning element or elements are aligned automatically and the subsequent mounting of the control circuit board on this positioning element or elements can be effected simply and precisely. As a result, the risk of damage during mounting is reduced, in particular also in the case of automated mounting methods.

The connecting unit can preferably be fastened undetachably on the one or more fastening elements which project relative to the stator housing and/or to the connecting unit in an axial direction of the stator housing. The axial direction is predetermined by the rotor axis. The fastening elements can comprise, for example, one or more fastening pins or projections or so-called bobbins projecting axially at the front, onto which the connecting unit is pushed axially and fixed with corresponding fastening openings, for example by riveting, press-fitting, or the like. Precise alignment of the connecting unit relative to the stator housing can be effected by fastening elements which interact in form-fitting fashion.

The positioning elements can preferably have at least one positioning pin which extends in an axial direction and onto which the control housing and the control circuit board with corresponding positioning sockets are pushed in the axial direction. Pushing them on axially enables particularly simple mounting. Socket openings in the control circuit board and/or the control housing can be formed as positioning sockets at low cost.

During the mounting, it can be provided that the control housing is positioned on a first positioning section of the positioning element and the control circuit board is positioned on a second positioning section. The positioning transversely to the mounting direction can be effected simply by form-fitting engagement of the respective positioning section in a corresponding positioning socket or opening. For example, a positioning pin can be stepped and have axially successive positioning sections with a different diameter and/or cross-section. For mounting, first the control housing, and then the control circuit board, can be pushed axially onto the first positioning section.

The control circuit board can be fixed to at least one of the positioning elements, for example by an undetachable or detachable connection. As a result, the control housing can simultaneously be fixed on the positioning pin.

During the mounting, it can preferably be provided that electrical connecting elements of the connecting unit are electrically connected to corresponding connection elements on the stator and the control circuit board. The electrical connection can be produced together or simultaneously with the mechanical connection, for example by soldering, crimping, or the like, or alternatively by detachable plug connectors or the like.

After the control housing has been mounted on the stator housing and the control circuit board has been attached in the control housing, the latter can be closed by attaching a cover or a control housing lid such that the control circuit board is preferably enclosed in sealing fashion.

At least one neutral point connector can be attached to the connecting body. A neutral point connector is formed from material that is a good conductor, for example from copper, and in each case has at least three contact elements such as contact tabs or lugs which can be connected conductively at the neutral point to those ends of the winding wires of the three phase windings which are on the neutral point side. A neutral point connector can be formed, for example, as a sheet-metal or wire part and attached preferably undetachably to the connecting body of the connecting unit, for example by welding. The contact elements can likewise be angled at the neutral point connector as illustrated and project from the connecting unit in the direction of the rotor axis. An advantage is that the neutral point can be integrated with the connecting unit at low cost, as a result of which mounting can be facilitated and a saving can be made in structural space.

### DESCRIPTION OF THE DRAWINGS

Advantageous embodiments of the invention are explained in detail below with the aid of the drawings, in which:

FIG. 1 shows a power-assisted steering system for a motor vehicle in a schematic perspective illustration,

FIG. 2 shows a drive unit of a power-assisted steering system according to FIG. 1,

FIG. 3 shows the drive unit according to FIG. 2 in a schematic illustration in which it is pulled apart in the axial direction,

FIG. 4 shows a schematic illustration of the drive unit according to FIG. 2 or 3 in a first mounting state of the method according to the invention,

FIG. 5 shows a schematic illustration in a second mounting state, following FIG. 4,

FIG. 6 shows a schematic illustration in a third mounting state, following FIG. 5,

FIG. 7 shows a side view of the mounting state shown in FIG. 5,

FIG. 8 shows a schematic illustration in a fourth mounting state, following FIG. 6,

FIG. 9 shows a schematic illustration in a fifth mounting state, following FIG. 8,

FIG. 10 shows a schematic illustration in a sixth mounting state, following FIG. 9,

FIG. 11 shows a schematic illustration in in the fully mounted final state, as in FIG. 2,

FIG. 12 shows a connecting unit of a drive unit according to FIGS. 1 to 11 in a schematically pulled-apart illustration,

FIG. 13 shows a schematic illustration of the drive unit in a second embodiment in a first mounting state in a view corresponding to FIG. 8,

FIG. 14 shows the drive unit according to FIG. 13 in a view corresponding to FIG. 5,

FIG. 15 shows the drive unit according to FIG. 14 in a view corresponding to FIG. 4,

FIG. 16 shows a connecting unit of a drive unit according to FIGS. 13 to 15 in a schematic perspective view,

FIG. 17 shows the connecting unit according to FIG. 16 in a further schematic perspective view similar to FIG. 4,

FIG. 18 shows a connecting unit of a drive unit according to FIGS. 13 to 17 in a schematically pulled-apart illustration.

### EMBODIMENTS OF THE INVENTION

In the different Figures, the same parts are at all times provided with the same reference symbols and are therefore generally also each mentioned only once.

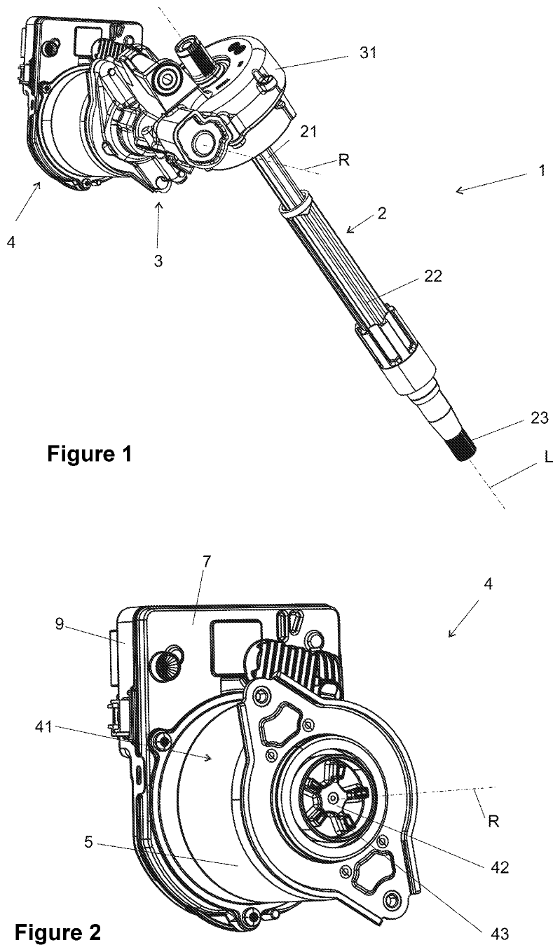

FIG. 1 shows a power-assisted steering system 1 which is attached to a steering shaft 2 which is mounted rotatably about its longitudinal axis L, the steering shaft axis. The steering shaft 2 has an inner shaft 21 which is arranged in an outer shaft 2 in torque-locking fashion and so that it can be adjusted telescopically in the longitudinal direction. At its rear end with respect to the driving direction, the steering shaft 2 has a fastening section 23 for attaching a steering wheel (not illustrated).

An electrical power-assistance drive 3 has a gearbox, preferably a worm gear, the output wheel of which is coupled non-rotatably to the steering shaft 2, namely to the inner shaft 21.

A drive unit 4 according to the invention, which is shown separately in a dismounted state in FIG. 2, is attached to the gearbox 31 on the input side.

The drive unit 4 has an electric motor 41. The motor 41 has a stator housing 5 in which a rotor shaft 42 is mounted rotatably about a rotor axis R. The rotor axis R defines the axial direction of the drive unit 4. A clutch 43, which can be designed as a claw clutch in this example, is attached to the rotor shaft 42 on the gearbox side for the purpose of torque-locking connection to the gearbox 31.

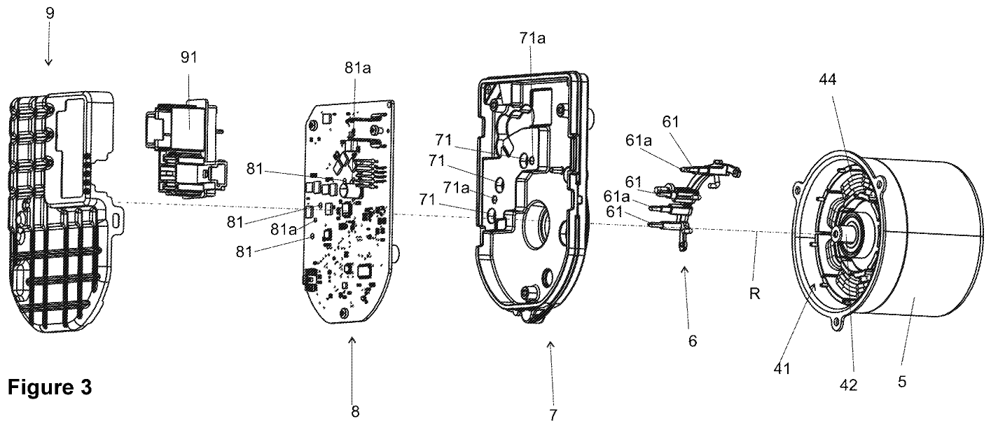

FIG. 3 shows the drive unit 4 in an exploded illustration in which the individual components are illustrated, pulled apart in the axial direction of the rotor axis R.

Phase windings 44 are attached in the stator housing 5.

A connecting unit 6, which has positioning elements designed as positioning pins 61 projecting in parallel and axially, is attached to the stator housing 5 axially on the side remote from the gearbox 31.

A control housing 7, which protrudes beyond the cross-section of the stator housing 5 transversely to the rotor axis R and has positioning sockets designed as through openings 71 into which the positioning pins 61 can be pushed in the axial direction and which house the latter in form-fitting fashion, is attached to the stator housing 5.

A control circuit board 8, also referred to as a printed circuit board or PCB and on which a control circuit with non-electronic components is constructed and interconnected, is arranged in an interior, remote from the stator housing 5, of the control housing 7. It has positioning sockets designed as through openings 81 which are axially aligned with the positioning sockets 71 of the connecting unit 7. The positioning pins 61 are designed such that in the mounted state they project axially from the control housing 7 through the through openings 71 and can be pushed axially into the through openings 81 of the control circuit board 8 for mounting.

By attaching a lid 9, the control circuit board 8 is enclosed tightly in the control housing 7. A plug housing 91, into which an electrical connector (not illustrated) can be plugged for connection to power-supply contacts of the control circuit board 8, is attached between the lid 9 and the control circuit board 8.

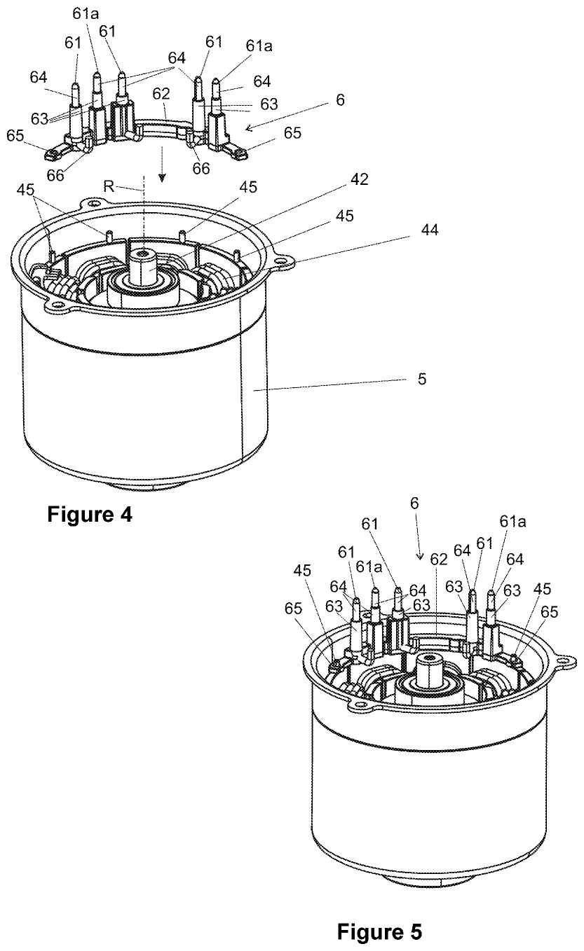

The production of a drive unit 1 according to the method according to the invention is shown in successive mounting states in FIGS. 4 to 10.

It can be seen in FIG. 4 that the connecting unit 6 has a common connecting body 62, designed as a plastic injection-molded part, from which the positioning pins 61 protrude axially. The positioning pins 61 have a first positioning section 63 which is formed by a plastic overmolding of electrically conductive contact pins which are made from a metal material that is a good conductor. The contact pins 64 projecting axially from the first positioning section 63 form second positioning sections 64 which have a smaller cross-section than the first positioning sections 63. The positioning pins 61 are thus designed so that they are stepped in the axial direction.

The connecting body 62 has axial through fastening openings 65 which correspond with axially projecting pin-shaped fastening projections 45, so-called bobbins, on the stator housing 5.

Starting from the mounting state shown in FIG. 4, the connecting unit 6 is moved in the direction of the arrow axially toward the stator housing 5 until the fastening projections 45 penetrate the fastening openings 65 in form-fitting fashion and are secured there by caulking, riveting, adhesive bonding, or the like such that the connecting unit is fixed as shown in FIG. 5.

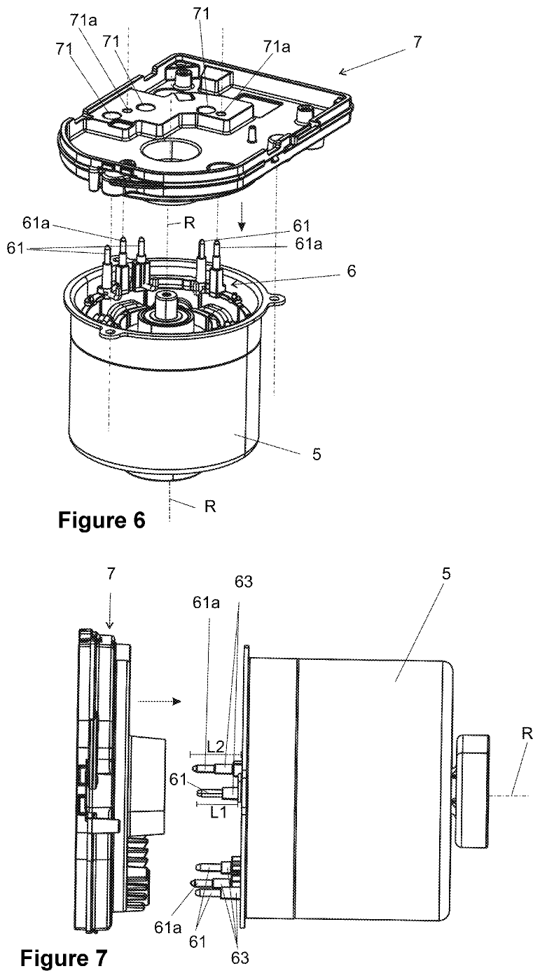

In the next step, as shown in FIGS. 6 and 7, the control housing 7 is positioned relative to the stator housing 5 such that the through openings 71 are axially aligned with the positioning pins 61.

It can be clearly seen in the side view transversely to the axial direction in FIG. 7 that, in the example shown, two of the positioning pins 61a project axially further than the others, and the positioning pins 61 have a length or height L2 which is longer than the length L1 of the positioning pins 61. If the control housing 7 is then moved axially toward the stator housing 5 for mounting, the positioning pins 61a first penetrate the associated through openings 71a, as a result of which relative orientation and alignment of the control housing 7 are effected such that the insertion of the other positioning pins 61 into the associated through openings 71 is ensured. The through openings 71, 71a of the control housing 7 can have different diameters so that the positioning pins 61, 61a can be positioned and pushed through more simply.

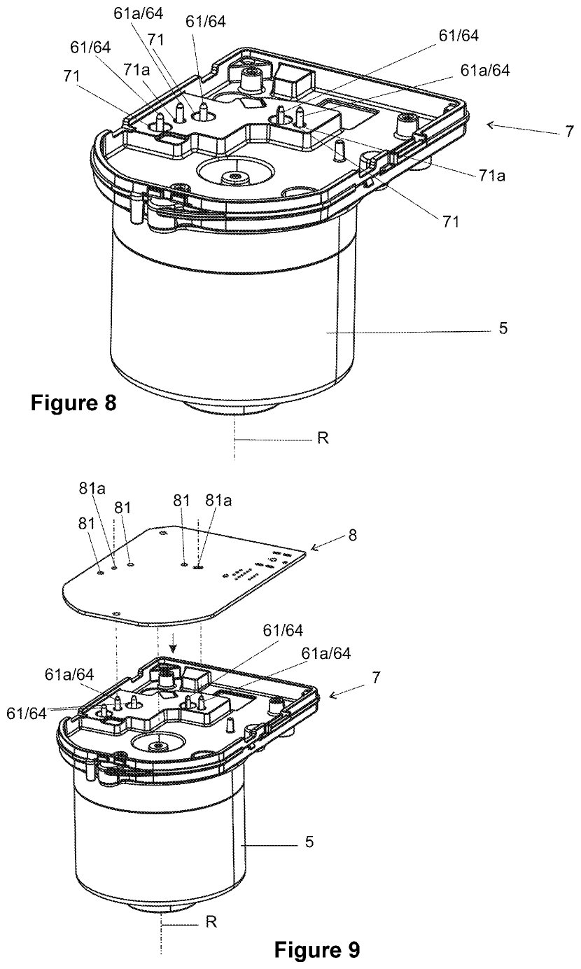

In the mounting state shown in FIG. 8, the control housing 7 is positioned relative to the connecting unit 6 and hence also to the stator housing 5 by the positioning pins 61, 61a passing through the through openings 71, 71a in form-fitting fashion with their first positioning sections 63 (see FIG. 7). The second positioning sections 64 of the positioning pins 61, 61a thus project axially from the control housing 7.

The control circuit board 8 is then, as shown in FIG. 9, positioned axially relative to the control housing 7 such that the through openings 81 are axially aligned with the positioning pins 61, namely with the positioning sections 64 projecting axially from the control housing 7.

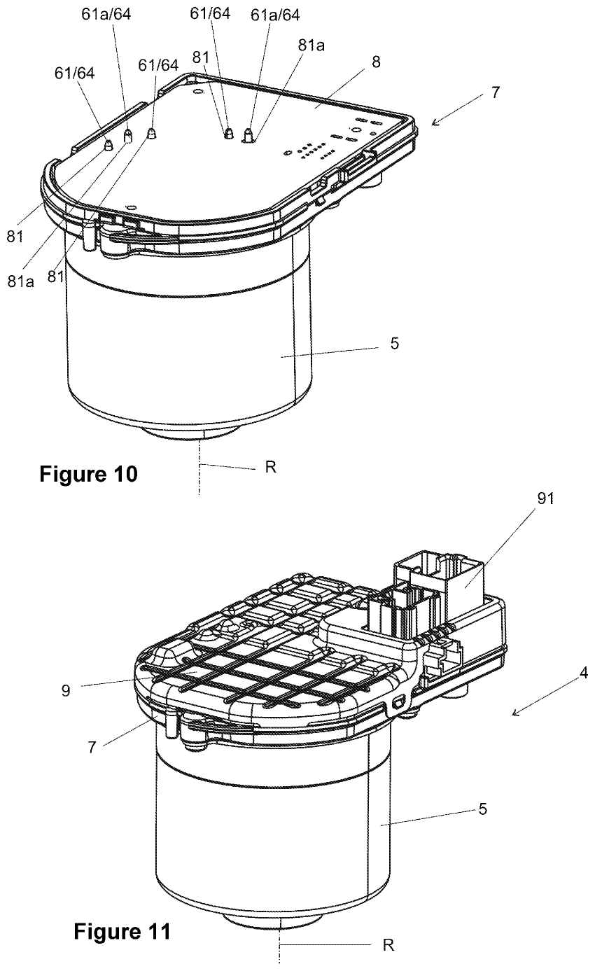

The control circuit board 8 is thereupon moved in the axial direction toward the control housing 7 until first the axially further projecting positioning pins 61a, and then the other positioning pins 61, are pushed through the corresponding through openings 81a until the mounting state shown in FIG. 10 is obtained. The control circuit board 8 is now situated in the control housing 7 and, like the latter, is aligned on the same positioning pins 61 transversely to the axial direction. Because the internal diameter of the through openings 81 is adapted so that it matches exactly the diameter or cross-section of the second positioning sections 64, precise positioning can be produced. In order to avoid mechanical redundancy and stress states, individual or multiple through openings 81, 81a are designed as elongated holes which have play in the transverse direction, as a result of which the alignment of the control circuit board 8 relative to the control housing 7 is, however, not adversely affected. The through openings 81, 81a of the control circuit board 8 can have different diameters so that the positioning pins 61, 61a can be positioned and pushed through more simply.

In the mounting state in FIG. 10, the control circuit board 8 sits axially on the axial step surface formed between the first positioning sections 63 and the second positioning sections 64. As a result, precise axial positioning of the control circuit board 8 relative to the control housing 7 is additionally enabled. The positioning pins 61, 61a consequently have a positioning effect simultaneously in and transversely to the axial direction.

The projecting positioning sections 64 can be connected to the control circuit board 8, for example by soldering. As a result, in addition to the mechanical positioning and fixing, a conductive connection is produced between the contact pins having the second positioning sections 64 and the control circuit constructed on the control circuit board 8.

The control housing 7 is then closed by the axial attachment of the lid 9 such that the control circuit board 8 is enclosed therein, as in the final state of mounting in FIG. 11, which corresponds to the state in FIG. 2. The plug housing 91 can be clamped, for example, between the lid 9 and the control circuit board 8.

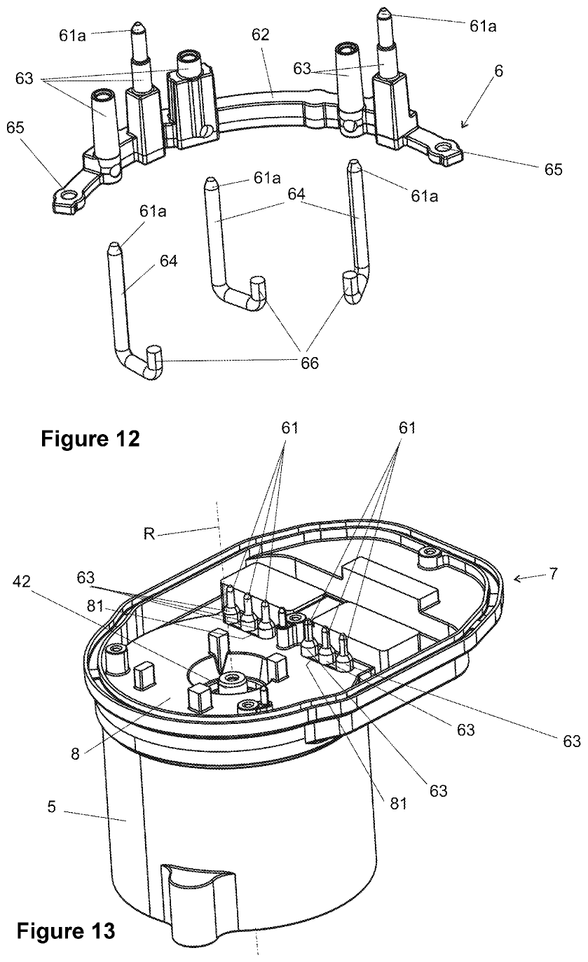

The connecting unit 6 is illustrated in FIG. 12, schematically pulled apart, wherein the second positioning sections 64 which are formed by metal contact pins 64, preferably formed from wire, are illustrated separately from the connecting body formed from the plastic injection-molding process. The bent connecting sections 66 can be clearly seen here which face essentially in the same direction (upward in the drawings) as the contact pins 64 but are here considerably shorter. These connecting sections 66 can be connected conductively to the phase windings 44, for example by crimping, press-fitting, soldering, and/or welding, or the like to the ends of the winding wire of these phase windings 44.

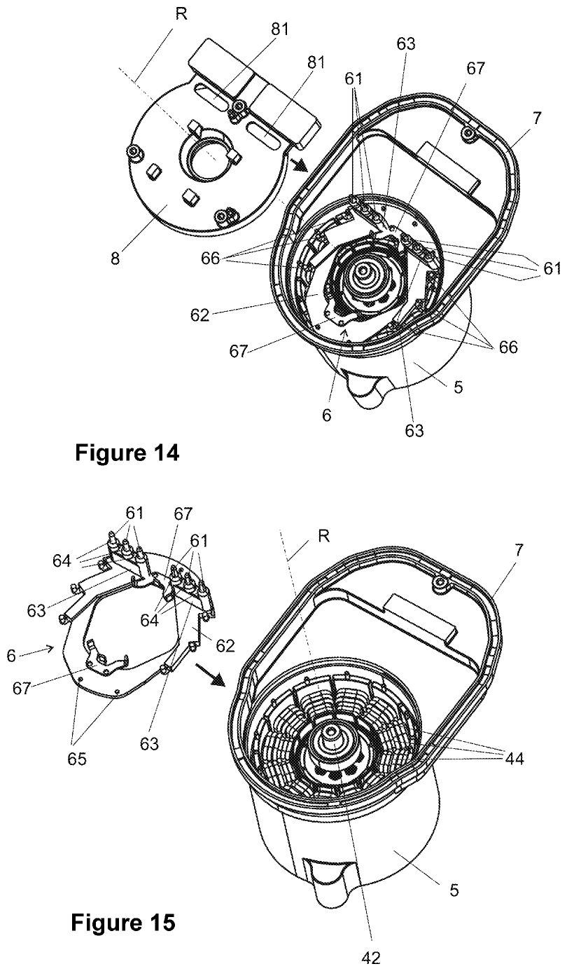

FIGS. 13, 14, and 15 show a second embodiment of a drive unit 4 according to the invention, wherein the same reference symbols are used for parts which have the same effect. The view in FIG. 13 corresponds to the view in FIG. 8, in FIG. 14 to FIG. 9, and in FIG. 15 to FIG. 4 together with FIG. 9.

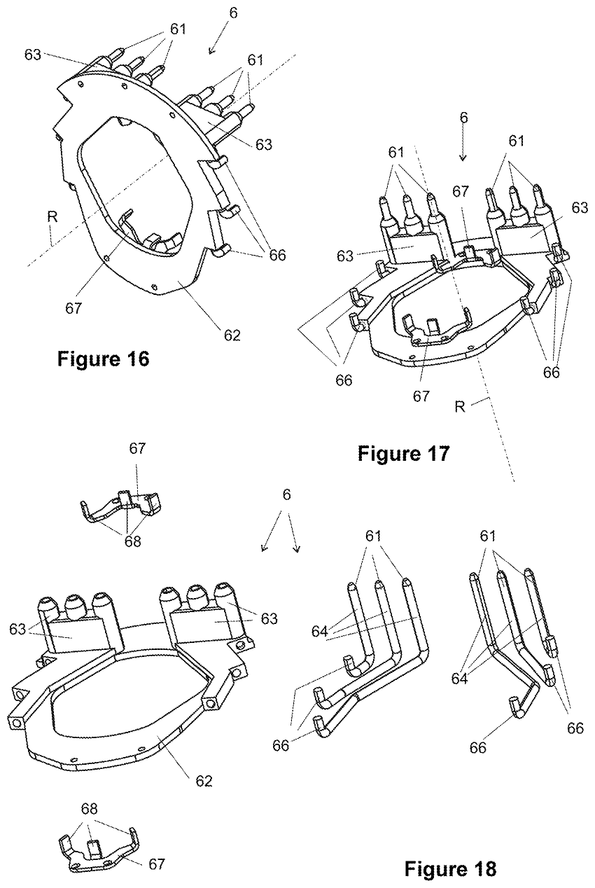

The connecting unit 6 in the second embodiment is shown in FIG. 17 in a perspective view as for the first embodiment in FIG. 4, and in FIG. 16 in a further perspective view. FIG. 18 shows a schematically pulled-apart illustration similar to FIG. 12.

It can be seen with the aid of the separate illustration in FIGS. 16 and 17 that the connecting unit 6 has a flat connecting body 62 which is annular with respect to the rotor axis R and can likewise preferably be formed as a plastic injection-molded part. Contact pins 64 formed from wire sections, also referred to as second positioning pins, are firmly embedded in the connecting body 62, preferably by overmolding with the plastic in the injection-molding process. The end sections, formed by the contact pins 64 and projecting parallel to the rotor axis R, of the contact pins 64 form positioning pins 61. It can clearly be seen here in FIG. 17 that all the positioning pins 61 project axially from the connecting body 62 by the same amount.

The positioning pins 61 are passed through positioning sections 63 which are formed as a single piece with the connecting body 62 and project axially from the latter in the direction of the rotor axis R,

Two neutral point connectors 67, which can be formed, for example, as sheet-metal parts, are attached preferably undetachably to the connecting body 62, for example by welding. The neutral point connectors 67 are formed from a material which is a good conductor, for example from copper, and each have at least three contact tabs 68 which can be connected conductively at the neutral point to those ends of the winding wires of the three phase windings 44 which are on the neutral point side. The contact tabs 68 can likewise, as illustrated, be angled at the neutral point connector and project in the direction of the rotor axis R.

The connecting unit 6 is inserted axially into the stator housing 5 in the direction of the rotor axis R, as indicated by the arrow in FIG. 15. The rotor shaft 42 here passes through the center of the annular connecting body 62.

In the second embodiment shown, when the connecting unit 6 is mounted, the control housing 7 can be already attached to the stator housing 5. Otherwise, mounting is effected as above with reference to FIGS. 4 and 5. The detailed manner in which this is effected is explained above in connection with FIG. 3.

When the connecting unit 6 is inserted, as illustrated in FIG. 14, the stator windings 44 are connected to the connecting sections 66 of the contact pins 64 and the contact tabs 68 of the neutral point connectors 67.

The control circuit board 8 is then inserted into the stator housing 5 in the axial direction predetermined by the rotor axis R, as indicated by the arrow in FIG. 14. The positioning pins 61 and the positioning sections 63 thus come into engagement with the through openings 81 in the control circuit board 8, as a result of which the latter is fixed in position.

FIG. 18 shows a schematically pulled-apart illustration of the connecting unit 6. The contact pins 64 formed by wire sections are embedded in the connecting body 62 formed as a plastic injection-molded part, as has already been described above for the first embodiment in FIG. 12. The neutral point connectors 67 can likewise be injection-molded or be attached later.

### LIST OF REFERENCE SYMBOLS

1 power-assisted steering system
2 steering shaft
21 inner shaft
22 outer shaft
23 fastening section
3 power-assistance drive
31 gearbox
4 drive unit
41 motor
42 rotor shaft
43 clutch
44 phase winding
45 fastening projections
5 stator housing
6 connecting unit
61,61a positioning pins
62 connecting body
63 first positioning section
64 second positioning section (contact pin)
65 fastening openings
66 connecting sections
67 neutral point connector
68 contact tabs
7 control housing
71 through openings
8 control circuit board
81 through openings
9 lid
91 plug housing
R rotor axis

1.-13. (canceled)

14. A drive unit for an electrical power-assisted steering system of a motor vehicle, comprising:
an electric motor with a stator housing that is attached to a control housing;
a control circuit board disposed in the control housing; and
a connecting unit attached to the stator housing, the connecting unit having electrical connecting elements and a positioning element, wherein the electrical connecting elements are electrically connected to the electric motor and to the control circuit board, wherein the positioning element interacts with the control circuit board for the purpose of relative positioning, wherein the positioning element interacts with the control housing for the purpose of relative positioning.

15. The drive unit of claim 14 wherein the positioning element engages in a form-fitting manner in a corresponding positioning socket in the control housing.

16. The drive unit of claim 14 wherein the positioning element includes a positioning pin that is aligned in an axial direction.

17. The drive unit of claim 14 wherein the positioning element is a first positioning element, the first positioning element projecting farther from the stator housing than a second positioning element.

18. The drive unit of claim 14 wherein the positioning element includes a first positioning section for engaging in the control housing and a second positioning section for engaging in the control circuit board.

19. The drive unit of claim 14 wherein the positioning element includes a connecting element.

20. The drive unit of claim 14 wherein at least one of the connecting elements has a coating of non-conductive material at least in some places.

21. The drive unit of claim 14 wherein a side of the control housing that is remote from the stator housing is closed with a control housing lid.

22. A method for producing a drive unit for an electrical power-assisted steering system of a motor vehicle, in which a control housing, in which a control circuit board is arranged, is attached to a stator housing of an electric motor, wherein a connecting unit having electrical connecting elements and a positioning element is attached to the stator housing, the method comprising:
positioning and fixing the connecting unit on the stator housing;
aligning the control housing on the positioning element of the connecting unit and fixing the control housing relative to the stator housing; and
aligning the control circuit board on the positioning element and fixing the control circuit board relative to the stator housing.

23. The method of claim 22 comprising fastening undetachably the connecting unit on the positioning element that projects relative to the stator housing and/or to the connecting unit in an axial direction of the stator housing.

24. The method of claim 22 wherein the positioning element includes a positioning pin that extends in an axial direction and onto which the control housing and the control circuit board with corresponding positioning sockets are pushed in the axial direction.

25. The method of claim 24 wherein the control housing is positioned on a first positioning section of the positioning element and the control circuit board is positioned on a second positioning section of the positioning element.

26. The method of claim 22 wherein the electrical connecting elements of the connecting unit are electrically connected to corresponding connection elements of phase windings and the control circuit board.
